(19) United States
(12) Patent Application Publication
(10) Pub. No.: US 2005/0085035 A1
(43) Pub. Date: Apr. 21, 2005

(54) Heterojunction bipolar transistor and manufacturing method making the same

(76) Inventors: Chih-Chiang Shen, Hsinchu (TW); Chang-Jung Chu, Hsinchu (TW); Rui-Huang Cheng, Hsinchu (TW); Yong-Yin Chen, Hsinchu (TW); Norio Hayafuji, Hsinchu (TW); Chin-Kun Peng, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/687,648

(22) Filed: Oct. 20, 2003

(51) Int. Cl. H01L 29/739

(52) U.S. Cl. 438/235

(57) ABSTRACT

A method for improving a performance of a heterojunction bipolar transistor is provided. The method includes steps of providing a substrate; forming a first at least one semiconductor layer on the substrate; forming a second at least one semiconductor layer on the first at least one semiconductor layer; and inserting a thermal treatment process within the second at least one semiconductor layer so as to improve a performance of the heterojuntion bipolar transistor. Furthermore, the thermal treatment process is performed at a temperature ranged from 300° C. to 800° C.

### BACKGROUND OF THE INVENTION

1. Field of the Invention

The present invention relates to a heterojunction bipolar transistor and a manufacturing method making the same, and more particular to a heterojunction bipolar transistor and a manufacturing method making the same for improving impurity controllability and providing better device stability and reproducibility thereof.

2. Description of the Prior Art

With the drastic extension of a wireless communication network market, recently, a wireless communication using a microwave band began to emerge, and thus resulted in the giving of much attention on the development of a very high frequency device and the miniaturization and high performance pursuit thereof. Specifically, the AlGaAs/GaAs heterojunction bipolar transistor (HBT) is widely used over all of the markets. Thus, the HBT has been increasingly studied and developed.

In the heterojunction bipolar device, the thermal process for the materials thereof is the key factor and will affect the reliability thereof significantly. The published literatures (materials science and engineering B56 (2001) 284-288) disclosed a thermal treatment which is proceeded after a growth of the whole device to improve the thermal treatment effect.

However, this method has some disadvantages as follows:

The effect of this method described above is not obvious and the improvement is also limited.

Thus it can bee seen, the prior art described above still has some defects, is not a good design, however, and is urgently to be improved.

Because of the technical defects of described above, the applicant keeps on carving unflaggingly to develop the heterojunction bipolar transistor and the manufacturing method making the same through wholehearted experience and research.

### SUMMARY OF THE INVENTION

An object of the present invention is to provide a heterojunction bipolar transistor and a manufacturing method making the same for improving a burn-in effect and reducing [H] level in a base layer of the heterojunction bipolar transistor.

The present invention for achieving the purposes described above includes a method for manufacturing a heterojunction bipolar transistor. The method includes steps of providing a substrate; forming a first at least one semiconductor layer on the substrate; forming a second at least one semiconductor layer on the first at least one semiconductor layer; and inserting a thermal treatment process within the second at least one semiconductor layer so as to improve a performance of the heterojuntion bipolar transistor, wherein the first at least one semiconductor layer includes collector layers region, and a base layer region, and the second at least one semiconductor layer includes emitter layers region.

The first and second at least one layers are made of a material selected from a group consisting of a GaAs, an AlGaAs, an InGaP, an InGaAs, an AlInP, an InGaAs, an InAlAs, an InP, and a combination of III-V compound semiconductor materials thereof. Furthermore, the thermal treatment process is performed at a temperature ranged from 300° C. to 800° C.

The present invention further provides a heterojunction bipolar device having an improved performance. The heterojunction bipolar device includes a substrate; a first at least one semiconductor layer formed on the substrate; and a second at least one semiconductor layer formed on the first at least one semiconductor layer, wherein a stack includes the substrate, the first at least one semiconductor layer, and the second at least one semiconductor layer, and a thermal treatment process is subjected to be inserted within the second at least one semiconductor layer so as to improve a performance of the heterojunction bipolar device.

### BRIEF DESCRIPTION OF THE DRAWINGS

The drawings disclose an illustrative embodiment of the present invention which serves to exemplify the various advantages and objects hereof, and are as follows:

FIG. 1 shows a cross sectional view of the heterojunction bipolar device in a preferred embodiment according to the present invention;

FIG. 2(a) show a plot of [H] level in the base layer of the heterojunction bipolar device without any treatment in the prior art; and

FIG. 2(b) shows a plot of [H] level in the base layer of the heterojunction bipolar device in a preferred embodiment according to the present invention.

### DETAILED DESCRIPTION OF THE PREFERRED EMBODIMENT

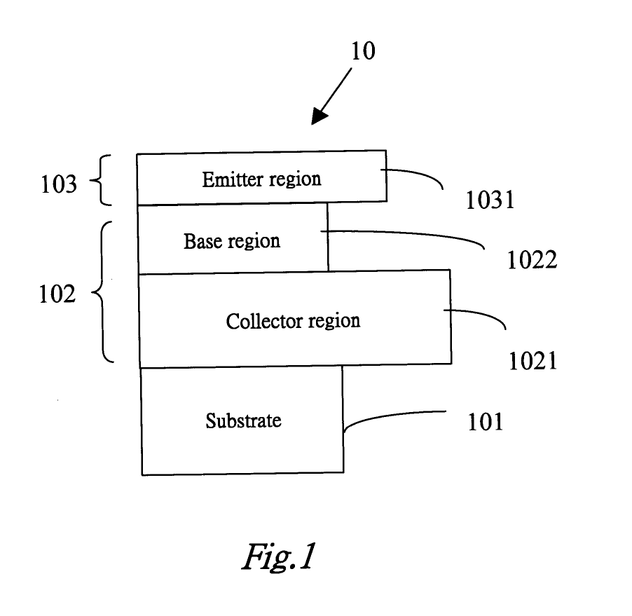

Please refer to FIG. 1 which illustrates a cross sectional view of the heterojunction bipolar device in a preferred embodiment according to the present invention. As shown in FIG. 1, a heterojunction bipolar device 10 includes a substrate 101, a first at least one semiconductor layer 102, and a second at least one semiconductor layer 103, which are sequentially formed on the substrate 101, wherein the first at least one semiconductor layer 102 comprises collector layers region 1021, and a base layer region 1022, and the second at least one semiconductor layer 103 comprises emitter layers region 1031.

All the semiconductor layers, including the first at least one semiconductor layer 102, and the second semiconductor layer 103, are made of a material which can be grown on the substrate 101, for example, but not limited, a GaAs, an AlGaAs, an InGaP, an InGaAs, an AlInP, an InGaAs, an InAlAs, an InP or a combination of III-V compound semiconductor materials thereof.

In addition, during fabricating the heterojunction bipolar device 10, except forming all these semiconductor layers described above, a thermal treatment process is further proceeded. Different from the conventional manufacturing processes which is performed after the whole device is completed, the thermal treatment process according to the present invention is proceeded within the second at least one semiconductor layer 103. In another word, after sequentially forming the collector layers region 1021, the base layer region 1022, and some of the emitter layers region 1031 on the substrate 101, the whole stack will be submitted to a thermal treatment process. And then, the rest emitter layers region, are sequentially formed on after the thermal treatment process is performed.

Moreover, the thermal treatment process can be performed at a temperature ranged from 300° C. to 800° C. And, the position and the conditions of the thermal treatment process can be adjusted properly depending on the device structure design.

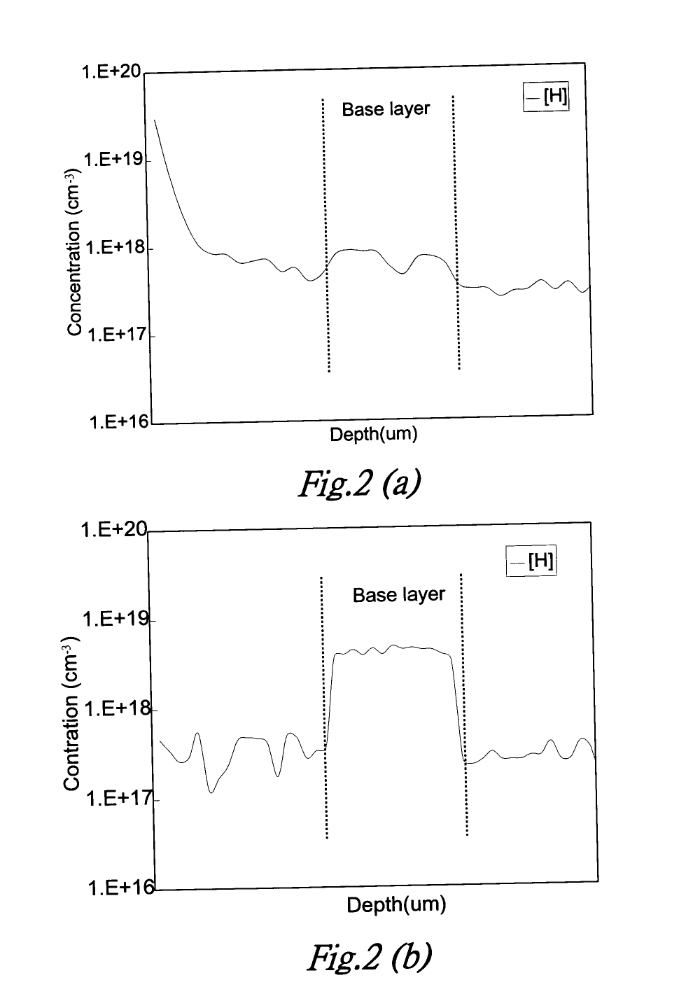

Furthermore, through performing the thermal treatment process during the manufacturing processes of the heterojunction bipolar device, the stability and reproducibility of the completed heterojunction bipolar device 10 can be improved. Please refer to FIGS. 2(a) and 2(b). FIG. 2(a) shows a plot of [H] level in the base layer of the heterojunction bipolar device without any treatment in the prior art, and FIG. 2(b) shows a plot of [H] level in the base layer of the heterojunction bipolar device in a preferred embodiment according to the present invention. When comparing FIG. 2(a) with FIG. 2(b), it can be obviously seen that the [H] level in the base layer is significantly dropped. That means the impurity level in the base layer is reduced. Since the impurity level thereof is reduced, the stability and performance of the heterojunction bipolar device can be improved, too.

Consequently, the heterojunction bipolar transistor and manufacturing method making the same according to the present invention, when being compared with the other prior arts, further includes the advantages as follows:

Better performance: The present invention can obviously improve the impurity ([H] level) controllability of the heterojunction bipolar transistor, so that the stability and reproducibility thereof can also be improved.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

1. A method for manufacturing a heterojunction bipolar transistor, comprising steps of:
providing a substrate;
forming a first at least one semiconductor layer on said substrate;
s; and
forming a second at least one semiconductor layer on said first at least one semiconductor layer; and
inserting a thermal treatment process within said second at least one semiconductor layer so as to improve a performance of said heterojuntion bipolar transistor.

2. The method according to claim 1, wherein said first at least one semiconductor layer comprises collector layers region, a base layer region.

3. The method according to claim 1, wherein said second at least one semiconductor layer comprises emitter layers region.

4. The method according to claim 1, wherein said first and second at least one layers are made of a material selected from a group consisting of a GaAs, an AlGaAs, an InGaP, an InGaAs, an AlInP, an InGaAs, an InAlAs, an InP, and a combination of III-V compound semiconductor materials thereof.

5. The method according to claim 1, wherein said thermal treatment process is performed at a temperature ranged from 300° C. to 800° C.

6. A heterojunction bipolar device, comprising:
a substrate;
a first at least one semiconductor layer formed on said substrate; and
a second at least one semiconductor layer formed on said first at least one semiconductor layer,
wherein a stack includes said substrate, said first at least one semiconductor layer, and said second at least one semiconductor layer, and a thermal treatment process is subjected to be inserted within said second at least one semiconductor layer so as to improve a performance of said heterojunction bipolar device.

7. The device according to claim 6, wherein said first at least one semiconductor layer comprises collector layers region, and a base layer region.

8. The device according to claim 6, wherein said second at least one semiconductor layer comprises emitter layers region.

9. The device according to claim 6, wherein said first and second at least one layers are made of a material selected from a group consisting of a GaAs, an AlGaAs, an InGaP, an InGaAs, an AlInP, an InGaAs, an InAlAs, an InP, and a combination of Ill-V compound semiconductor materials thereof.

10. The device according to claim 6, wherein said thermal treatment process is performed at a temperature ranged from 300° C. to 800° C.
